(19) United States
(12) Patent Application Publication
(10) Pub. No.: US 2004/0169174 A1
(43) Pub. Date: Sep. 2, 2004

(54) Container for encapsulating oled and manufacturing method thereof

(76) Inventors: Jin Woo Huh, Gyoungki-do (KR); Jae Yeol Oh, Gyoungki-do (KR)

Correspondence Address: Merchant & Gould, PO Box 2903, Minneapolis, MN, 55402-0903, US

(21) Appl. No.: 10/478,780

(22) PCT Filed: May 24, 2002
(86) PCT No.: PCT/KR02/00994

(30) Foreign Application Priority Data
May 24, 2001 (KR) 2001-28629

(51) Int. Cl. H01L 35/24

(52) U.S. Cl. 257/40

(57) ABSTRACT

The present invention relates to a container for encapsulating organic light emitting diodes (hereinafter, referred to as OLED) and a manufacturing method thereof, wherein a container for encapsulating OLEDs is manufactured by forming a sealant in a glass sheet using a glass frit, thereby resulting in improving the characteristic of junction between the container and the top substrate.

### BACKGROUND OF THE INVENTION

1. Field of the Invention

The present invention relates to a container for encapsulating organic light emitting diodes (hereinafter, referred to as “OLED”) and a manufacturing method thereof, wherein a container for encapsulating OLEDs is manufactured by forming a lateral wall in a glass sheet using a glass frit, thereby resulting in improving the junction characteristic between the container and the top substrate.

2. Description of the Prior Art

An OLED comprises a top substrate whereon organic substance is stacked and a container for encapsulation. The top substrate has a glass substrate whereon an anode ITO, an organic thin film and a cathode are stacked. On the organic thin film are formed a hole injecting layer ‘HIL’, hole transport layer ‘HTL’, electron transport layer ‘ETL’ and electron injecting layer ‘EIL’.

A container for encapsulation is formed of a metal plate using a metal mold.

The OLED is formed by arranging and connecting the above-described substrate and the container for encapsulation.

In the above-described conventional OLED, a container for encapsulation is formed of metal. As a result, if the surface has high roughness, the junction of the container and the top substrate is difficult or a leak may be generated. Furthermore, if the area becomes larger, the surface of the container may not have the desired roughness. Accordingly, there is a limit to enlarge the size of an OLED.

In addition, the conventional container has the low junction strength because its material is metal. It is also difficult to maintain the junction condition because the container has the different thermal expansive coefficient from that of the top substrate formed of glass.

### SUMMARY OF THE INVENTION

Accordingly, the present invention has an object to provide a container for encapsulating OLEDS by forming a lateral wall on a glass sheet with a glass frit, thereby improving the junction characteristic of a container and a top substrate.

To achieve the above-described object, a container for encapsulating OLEDs according to the present invention comprises a glass sheet and a lateral wall formed of a glass frit including a binder, while a getter or an absorbent is mounted between lateral walls.

The lateral wall is formed by coating and burning the glass frit on the glass sheet corresponding to the size and the pattern of the top substrate to be encapsulated. A plurality of lateral walls are arranged on the glass sheet in a matrix structure. They may be formed of a stair structure.

A ceramic plate is formed instead of the glass sheet. Here, it is desirable to form a buffer film to relieve the stress resulting from the thermal expansive coefficient.

### BRIEF DESCRIPTION OF THE DRAWINGS

The present invention will be explained in terms of exemplary embodiments described in detail with reference to the accompanying drawings, which are given only by way of illustration and thus are not limitative of the present invention, wherein:

FIG. 1 is a diagram illustrating an example of a lateral wall formed to have lines and rows on a glass sheet in order to manufacture a container for encapsulating OLEDs in accordance with the present invention;

FIG. 2a is a cross-sectional diagram illustrating X-Y portion of FIG. 1 when a lateral wall is formed using dispensing or screen printing;

FIG. 2b is a cross-sectional diagram illustrating X-Y portion of FIG. 1 when a lateral wall is transformed to prevent its diffusion after dispensing;

FIG. 2c is a cross-sectional diagram illustrating X-Y portion of FIG. 1 when a lateral wall is transformed to consider taping for accepting an absorbent having powder condition;

FIG. 3a is a cross-sectional diagram illustrating an example wherein a getter is attached to the inside of the container;

FIG. 3b is a cross-sectional diagram illustrating an example wherein a film is taped by accepting the absorbent;

FIG. 4 is a cross-sectional diagram of a top substrate; and

FIG. 5 is a cross-sectional diagram of an encapsulated OLED.

### DETAILED DESCRIPTION OF THE PREFERRED EMBODIMENTS

A container for encapsulating OLEDs and a manufacturing method thereof in accordance with preferred embodiments of the present invention will be described in detail with reference to the accompanying drawings.

A plurality of containers for encapsulating OLEDs are manufactured on a glass sheet having a predetermined area to have a matrix structure. After a lateral wall is formed on the glass sheet, the glass sheet is cut into unit containers and used in encapsulation of a top substrate. In another way, the glass sheet may be cut into unit panels after encapsulationg of the glass sheet.

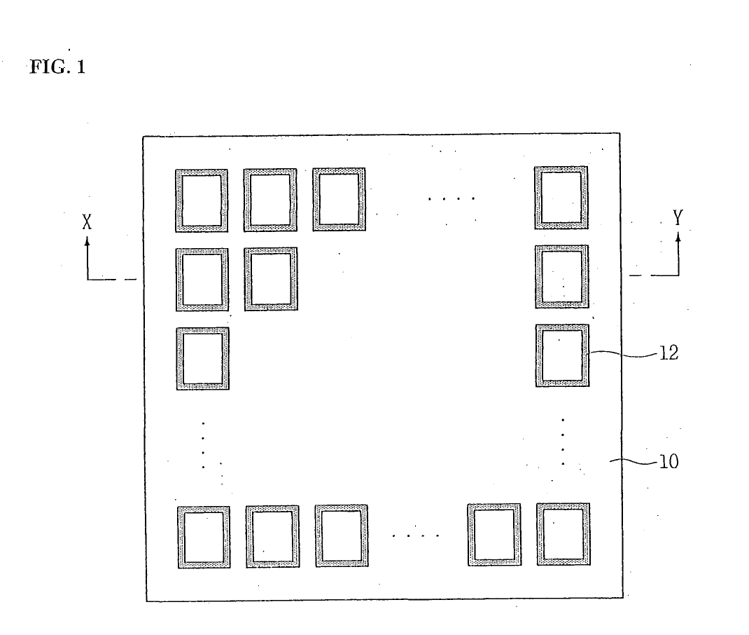

As shown in FIG. 1, a preferred embodiment in accordance with the present invention comprises a plurality of lateral walls 12 on a surface of a glass sheet 10. The plurality of lateral walls 12 are formed on the surface of the glass sheet 10 in a matrix structure having lines and rows. The lateral wall 12 is formed by coating and burning a glass frit. Here, it is desirable to include a binder in the glass frit.

The lateral wall 12 can-have various patterns.

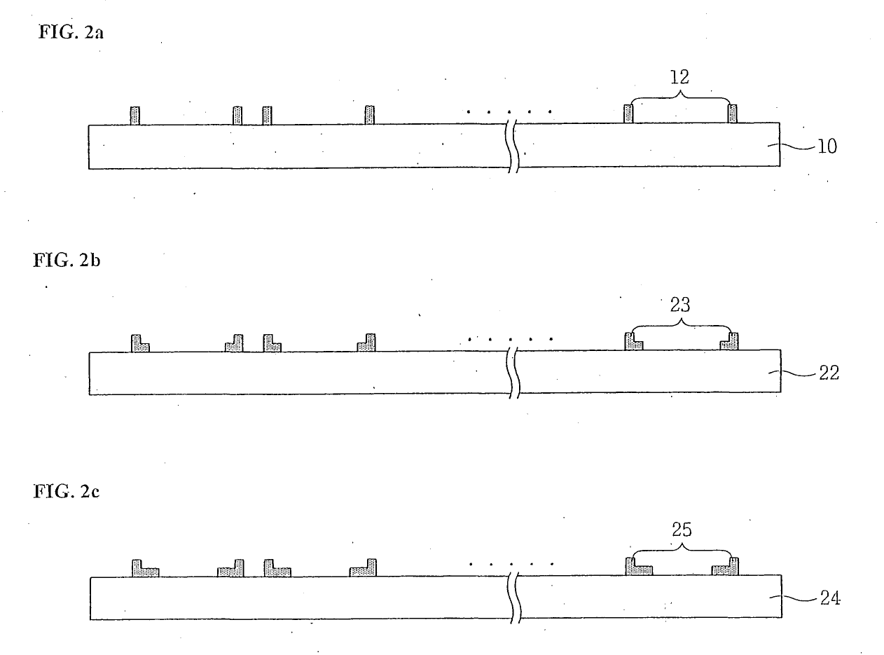

In a simpler way, the lateral wall 12 may be formed to have a cross section structure, as shown in FIG. 2a. In other words, the glass frit is coated on the glass sheet 10 to have a plane surface as shown in FIG. 1. Thereafter, if the glass frit is burned at a high temperature, as shown in FIG. 2a, the lateral wall 12 is formed-and the surface of the burned lateral wall 12 is polished. Here, the surface of the lateral wall 12 may be polished by a slurry made from mixing polishing powder in water or by a CMP (Chemical Mechanical Polisher) process.

The glass frit used in forming the lateral wall 12 has all kinds of colors ranging from white to black. The glass sheet 10 for encapsulation has a thickness of 0.3˜3 mm.

The above-described glass frit may be coated by dispensing or screen printing. Here, dispensing has a nozzle on a surface of the glass sheet 10 so that the glass frit may have a predetermined pattern and size. Screen printing is a method for printing a desired pattern on the glass sheet 10. In this method, a desired pattern is first designed and drawn on the metal sheet having a net structure.

Then, the portion without the pattern is masked using emulsion liquid, and the glass frit is planed with a squeeze. As a result, the desired pattern is printed on the glass sheet.

The coatable glass frit is hardened and burned while the binder mixed at a temperature of 400˜500° C. is removed. As a result, the burned glass frit forms the lateral wall 12. It is desirable that the surface of the lateral wall 12 should be polished to have an easy junction with the top substrate.

As shown in FIG. 2b, a lateral wall 23 is formed to prevent the diffusion after dispensing.

In detail, the lateral wall 23 of FIG. 2b has a cross section wherein stairs are formed on the inside of outlines in rectangle. This cross section having a stair structure is formed by twice coating. That is, first, a glass frit is widely coated to have a rectangle on a glass sheet 22 using screen printing. Then, a glass frit is narrowly coated on the second coated glass frit using a dispensing method. As a result, the lateral wall 23 is formed. Here, it is desirable to bum the glass frit in each step in order to prevent the diffusion of the glass frit after dispensing.

An absorbent having powder condition is injected on a glass sheet 24 between lateral walls 25 and then may be taped to be sealed. For this process, a stair surface is widely formed on the lateral wall 25, as shown in FIG. 2c.

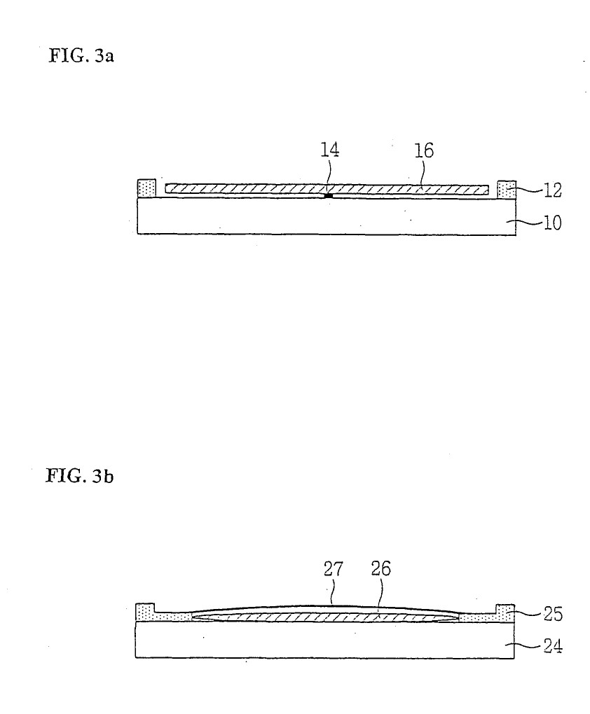

Referring to FIG. 3b, an absorbent 26 having powder condition is injected on a glass sheet 24 between the lateral walls 25. A protective film 27 is formed above the absorbent 26 to seal the absorbent 26 between the lateral walls 25. The absorbent 26 is sealed because the end portion of the protective film 27 is taped on the stair surface of the lateral walls 25. It is desirable to form the wide stair surface in order to attach the adhesive tape to the stair sruface easily.

Unlike FIGS. 2a through 2c, the height and the pattern of lateral walls may be transformed in various ways, in consideration of a getter or an absorbent to be placed in a container.

A getter or an absorbent should be attached or placed in a container for encapsulating OLEDs.

As shown in FIG. 3a, in a container of OLEDS, a getter 16 may be attached to a gap formed between the lateral walls 12 using an adhesive.

In other words, the getter 16 is placed on the container wherein the lateral walls 12 having the cross section of FIG. 2a are formed. Here, it is desirable to design the height of the lateral walls 12 in consideration of that of the getter 16.

As shown in FIG. 3b, the absorbent 26 may be placed on the container wherein the lateral walls 25 having the cross section of FIG. 2c are formed.

Here, the absorbent 26 is injected on the glass sheet 24 between the lateral walls 25. The protective film 27 as an adhesive tape is taped between the stair surface of the lateral walls 25 to seal the absorbent having powder condition. The protective film 27 may be formed of porous cloth to help the function of the absorbent 26. The protective film 27 may also be formed of a built-in adhesive tape. Materials in powder condition such as barium oxide or zeolite may be used as the absorbent 26.

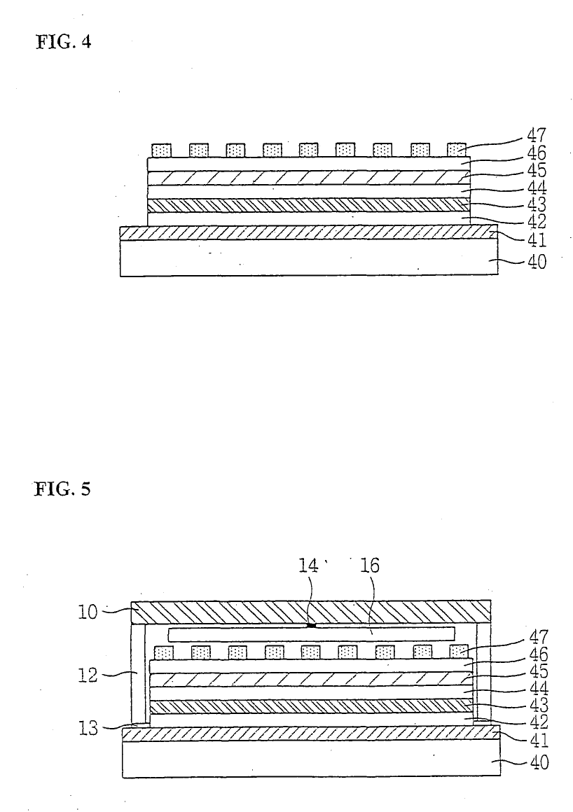

The container as described above in FIGS. 1 through 3b is manufactured as an OLED while the top substrate having the cross section of FIG. 4 is encapsulated.

The top substrate of FIG. 4 has a stacked structure wherein an anode 41, a hole injecting layer 42, a hole transport layer 43, an organic film 44, an electron transport layer 45, an electron injecting layer 46 and a cathode 47 are sequentially stacked on a glass substrate 40.

The transparent anode 41 formed of indium tin oxide ‘ITO’ is first formed on the glass substrate 40. Then, an insulating film (not shown) and an auxiliary electrode (not shown) are formed. A separating film for determining the separation of RGB pictures and the pattern of cathode electrodes is formed of negative polyimide photo resist to have a reverse picture sidewall.

Thereafter, a hole injecting layer 42, a hole transport layer 43, an organic film 44, an electron transport layer 45, an electron injecting layer 46 and a cathode. 47 are sequentially in a vacuum chamber.

The top substrate having the above-described structure is encapsulated as a container in accordance with various preferred embodiments of the present invention. For example, the top substrate of FIG. 4 is encapsulated as a container wherein a getter 16 is attached to a glass sheet 10, as shown in FIG. 5.

In other words, an adhesive 13 is coated on the top substrate of FIG. 4 and the surface of the lateral wall 12 in a container for encapsulation of FIG. 3a. Then, the top substrate of FIG. 4 and the lateral wall 12 of the glass sheet 10 of FIG. 3a are connected using the adhesive 13 in a chamber having a inactive gas as shown in FIG. 5. Such kinds of adhesives as adhesive 14 used in mounting the getter 16 may be used as the adhesive 13. Here, it is desirable to use an adhesive for attaching the object using ultraviolet hardening as the adhesive 13.

In another way, an OLED may be manufactured by connecting the top substrate of FIG. 4 and the container wherein the absorbent 26 of FIG. 3b or 3c is injected.

A container wherein a lateral wall is formed on a ceramic plate instead of the above-described glass sheet using a glass frit in consideration of thermal expansive coefficient may be used in encapsulation. Here, a buffer layer may be formed between the lateral wall and the ceramic plate to buffer the difference of thermal expansive coefficient in the ceramic and the glass.

According to the present invention, a lateral wall can be formed without deformation of a glass sheet using a glass frit. Various patterns of lateral walls may also be formed to improve the adhesiveness on the glass sheet. The process where a lateral wall is formed in a container for encapsulating OLEDs is simple. The cost can be reduced in forming various patterns of lateral walls.

In addition, it is possible to prevent generation of leaks resulting from the stress due to the difference of thermal expansive coefficient because the thermal expansive coefficient is the same or similar in the container for encapsulation and the top substrate. Accordingly, the durability of OLEDs can be improved.

While the invention is susceptible to various modifications and alternative forms, specific embodiments have been shown by way of example in the drawings and described in detail herein. However, it should be understood that the invention is not limited to the particular forms disclosed. Rather, the invention covers all modifications, equivalents, and alternatives falling within the spirit and scope of the invention as defined in the appended claims.

What is claimed is:

1. A container for encapsulating OLEDs, comprising:
a glass sheet; and
a lateral wall formed by forming and burning a glass frit including a binder on the glass sheet.

2. The container for encapsulating OLEDs according to claim 1, further comprising an absorbing member in the inside of the lateral wall.

3. The container for encapsulating OLEDs according to claim 2, wherein the absorbing member comprises a getter adhering to the glass sheet between the lateral walls with adhesive.

4. The container for encapsulating OLEDs according to claim 2, wherein the absorbing member is formed by injecting an absorbent on the glass sheet between the lateral walls and taping the absorbent with a protective film.

5. The container for encapsulating OLEDs according to claim 4, wherein the protective film is formed of porous cloth.

6. The container for encapsulating OLEDs according to claim 1, wherein the lateral wall has a stair structure.

7. The container for encapsulating OLEDs according to claim 6, wherein the absorbing member is formed by injecting an absorbent on the glass sheet between the lateral walls, taping the absorbent with a protective film, and attaching the end of the protective film to a stair surface of the lateral wall.

8. The container for encapsulating OLEDs according to claim 1, wherein the glass sheet has a thickness of 0.3˜3 mm.

9. The container for encapsulating OLEDs according to claim 1, wherein a ceramic plate is formed instead of the glass sheet.

10. The container for encapsulating OLEDs according to claim 9, wherein a buffer film is further formed to alleviate the stress resulting from the difference of thermal expansive coefficient between the ceramic plate and the lateral wall.

11. A method of manufacturing a container for encapsulating OLEDs, comprising:
the first step of forming a glass frit including a binder on a glass sheet to have a predetermined form;
the second step of forming a lateral wall by burning the glass frit; and
the third step of polishing the surface of the lateral wall.

12. The method according to claim 11, further comprising the fourth step of mounting an absorbing member between the lateral walls

13. The method according to claim 12, wherein the fourth step is to mount the absorbing member by adhering a getter between the lateral walls.

14. The method according to claim 12, wherein the fourth step is to mount the absorbing member by performing the steps of: injecting an absorbent between the lateral walls; and taping the absorbent with a protective film.

15. The method according to claim 14, wherein the absorbent is calcium oxide, barium oxide or zeolite.

16. The method according to claim 14, wherein porous cloth is used as the protective film.

17. The method according to claim 11, wherein, if a ceramic plate is used instead of the glass sheet, a glass frit of the first step is formed by coating an insulating film used as a buffer film in the ceramic plate.

18. A method of manufacturing a container for encapsulating OLEDS, comprising:
the first step of forming a glass frit including a binder on a glass sheet to have a first width;
the second step of burning the glass frit having a first width;
the third step of forming the glass frit having a narrower width than the first width on the top portion of the burned glass frit;
the fourth step of forming a lateral wall having a stair structure by burning the glass frit of the third step;
the fifth step of polishing the surface of the lateral wall; and
the sixth step of mounting an absorbing member between the lateral walls.

19. A method of manufacturing a container for encapsulating OLEDs, comprising:
the first step of forming a glass frit including a binder on, a plurality of regions of a glass sheet;
the second step of forming a lateral wall by burning the glass frit; and
the third step of polishing the surface of the lateral wall.

20. The method according to claim 19, further comprising the fourth step of mounting an absorbing member between the lateral walls.

21. The method according to claim 20, wherein the fourth step is to mount the absorbing member by adhering a getter between the lateral walls.

22. The method according to claim 20, wherein the fourth, step is to mount the absorbing member by performing the steps of: injecting an absorbent between the lateral walls; and taping the absorbent with a protective film.

23. The method according to claim 20, wherein the absorbent is calcium oxide, barium oxide or zeolite.

24. The method according to claim 22, wherein porous cloth is used as the protective film.

25. The method according to claim 19, wherein, if a ceramic plate is used instead of the glass sheet, a glass frit of the first step is formed by coating an insulating firm used as a buffer film in the ceramic plate.

26. A method of manufacturing a container for encapsulating OLEDS, comprising:
the first step of forming a glass frit including a binder on a plurality of regions of a glass sheet to have a first width;
the second step of burning the glass frit having a first width;
the third step of forming the glass frit having a narrower width than the first width on the top portion of the burned glass frit;
the fourth step of forming a lateral wall having a stair structure by burning the glass frit of the third step;
the fifth step of polishing the surface of the lateral wall and
the sixth step of mounting an absorbing member between the lateral walls.
